(19) United States
(12) Patent Application Publication
(10) Pub. No.: US 2015/0287590 A1
(43) Pub. Date: Oct. 8, 2015

(54) METHOD OF RINSING AND DRYING SEMICONDUCTOR DEVICE AND METHOD OF MANUFACTURING SEMICONDUCTOR DEVICE USING THE SAME

(71) Applicant: SAMSUNG ELECTRONICS CO., LTD., Suwon-si (KR)

(72) Inventors: Jung-Min OH, Incheon (KR); Yongsun KO, Suwon-si (KR); Kwangsu KIM, Seoul (KR); SeokHoon KIM, Seongnam-si (KR); ChangSup MUN, Suwon-si (KR); Kuntack LEE, Suwon-si (KR); Hyosan LEE, Hwaseong-si (KR); Jihoon JEONG, Suwon-si (KR); Yong-Jhin CHO, Hwaseong-si (KR)

(21) Appl. No.: 14/669,354

(22) Filed: Mar. 26, 2015

(30) Foreign Application Priority Data
Apr. 3, 2014 (KR) 10-2014-0040043

(51) Int. Cl. H01L 21/02; H01L 21/311; H01L 21/3213

(52) U.S. Cl. CPC H01L 21/02101; H01L 21/02068; H01L 21/02063; H01L 21/32133; H01L 21/31111; H01L 21/02532; H01L 21/02595

(57) ABSTRACT

Provided is a method of rinsing and drying a semiconductor device, including forming a pattern on a substrate; rinsing the substrate, where the pattern is formed, using a rinse solution; loading the substrate into a dry chamber; injecting supercritical carbon dioxide into the dry chamber such that rinse solution remaining on the pattern is diluted to have a concentration below 2 percent by weight based on a weight of the rinse solution remaining on the pattern and the supercritical carbon dioxide; and venting the supercritical carbon dioxide such that the dry chamber is maintained at atmospheric pressure to dry the substrate where the pattern is formed.

### CROSS-REFERENCE TO RELATED APPLICATION

Korean Patent Application No. 10-2014-0040043, filed on Apr. 3, 2014, in the Korean Intellectual Property Office, and entitled: “Method Of Rinsing and Drying Semiconductor Device and Method Of Manufacturing Semiconductor Device Using the Same,” is incorporated by reference herein in its entirety.

### BACKGROUND

1. Field

Semiconductor devices are widely used in many electronic industries because of their characteristics such as, for example, small size, multi-functionality, and/or low fabrication cost. Semiconductor devices may include a memory device to store data, a logic device to calculate data, and a hybrid device to perform various functions at the same time.

2. Description of the Related Art

With increasing demand for high integration of semiconductor devices, there may arise various disadvantages such as reduction in a margin of an exposure process to define fine patterns, and it may become increasingly difficult to implement semiconductor devices. Various studies have been conducted to satisfy demands for high integration and/or high speed of semiconductor devices.

### SUMMARY

Embodiments may be realized by providing a method of rinsing and drying a semiconductor device, including forming a pattern on a substrate, rinsing the substrate, where the pattern is formed, using a rinse solution, loading the substrate into a dry chamber, injecting supercritical carbon dioxide into the dry chamber such that rinse solution remaining on the pattern is diluted to have a concentration below 2 percent by weight based on a weight of the rinse solution remaining on the pattern and the supercritical carbon dioxide, and venting the supercritical carbon dioxide such that the dry chamber is maintained at atmospheric pressure to dry the substrate where the pattern is formed.

Following injecting of the supercritical carbon dioxide, the method may include maintaining the dry chamber at a temperature of 40 degrees centigrade or higher and at a pressure of 80 bars or higher.

Rinsing the substrate may include loading the substrate on a spin module, supplying deionized water while the substrate is rotated by the spin module, and supplying a rinse solution including isopropyl alcohol while the substrate is rotated by the spin module.

Forming the pattern on the substrate may include etching the substrate to form a trench having an aspect ratio equal to or greater than 12.

Forming the pattern on the substrate may include forming a sacrificial pattern on the substrate, conformally forming a conductive layer on the sacrificial pattern, etching an upper portion of the conductive layer to form a node-separated storage electrode having an aspect ratio equal to or greater than 24, and removing the sacrificial pattern.

Forming the pattern on the substrate may include forming sacrificial layers of at least 48 stages and interlayer dielectrics between two adjacent sacrificial layers on the substrate, respectively, forming a vertical active pattern to penetrate the sacrificial layers and the interlayer dielectrics, etching the sacrificial layers and the interlayer dielectrics to form a trench extending in one direction, and removing the sacrificial layers.

Embodiments may be realized by providing a method of manufacturing a semiconductor device, including sequentially and alternately stacking sacrificial layers and interlayer dielectrics on a substrate, forming a through active pattern to penetrate the sacrificial layers and the interlayer dielectrics and to be electrically connected to the substrate, etching the sacrificial layers and the interlayer dielectrics in one direction to form a trench, removing the sacrificial layers exposed by the trench to form recesses, rinsing the substrate, where the interlayer dielectrics are formed, using a rinse solution, loading the substrate into a dry chamber, injecting supercritical carbon dioxide into the dry chamber such that the rinse solution remaining on the substrate where the interlayer dielectric are formed is diluted to have a concentration below 2 percent by weight based on a weight of the rinse solution remaining on the substrate and the supercritical carbon dioxide, venting the supercritical carbon dioxide to maintain the dry chamber at atmospheric pressure.

Removing the sacrificial layers exposed by the trench to form recesses may include forming at least 48 recesses.

The method may further include, following injecting the supercritical carbon dioxide, maintaining the dry chamber at a temperature of 40 degrees centigrade or higher and at a pressure of 80 bars or higher.

Embodiments may be realized by providing a method of manufacturing a semiconductor device, including forming a pattern on a substrate, lowering surface tension of a cleaning solution used on the pattern, and drying the substrate where pattern is formed.

The pattern may have an aspect ratio equal to or greater than 12.

The cleaning solution may include at least one of isopropyl alcohol and water.

Lowering surface tension of the cleaning solution may include diluting the cleaning solution with supercritical carbon dioxide.

The supercritical carbon dioxide may be at a pressure of 74.8 bar or higher and a temperature of 31.1 degrees centigrade or higher.

The cleaning solution may be diluted to have a concentration below 2 percent by weight based on a weight of the cleaning solution and the supercritical carbon dioxide.

Lowering surface tension of the cleaning solution may prevent leaning of the pattern.

### BRIEF DESCRIPTION OF THE DRAWINGS

Features will become apparent to those of skill in the art by describing in detail exemplary embodiments with reference to the attached drawings in which:

FIG. 1 illustrates a flowchart summarizing a method of rinsing and drying a semiconductor device according to an embodiment;

FIGS. 2A through 2D illustrate cross-sectional views of a method of manufacturing a semiconductor device according to an embodiment;

FIGS. 3A through 3G illustrate cross-sectional views of a method of manufacturing a semiconductor device according to an embodiment; and

FIGS. 4A through 4F illustrate cross-sectional views of a method of manufacturing a semiconductor device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the specification, it will be understood that when an element is referred to as being “on” another layer or substrate, it can be directly on the other element, or intervening elements may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. In the drawings, thicknesses of elements are exaggerated for clarity of illustration. Like reference numerals refer to like elements throughout.

Exemplary embodiments will be described below with reference to cross-sectional views, which are exemplary drawings. The exemplary drawings may be modified by manufacturing techniques and/or tolerances. Accordingly, the exemplary embodiments are not limited to specific configurations shown in the drawings, and include modifications based on the method of manufacturing the semiconductor device. For example, an etched region shown at a right angle may be formed in a rounded shape or formed to have a predetermined curvature. Therefore, regions shown in the drawings have schematic characteristics. In addition, the shapes of the regions shown in the drawings exemplify specific shapes of regions in an element. Though terms like a first, a second, and a third are used to describe various elements in various embodiments, the elements are not limited to these terms. These terms are used only to tell one element from another element. An embodiment described and exemplified herein includes a complementary embodiment thereof.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

The terms used in the specification are for the purpose of describing particular embodiments only and are not intended to be limiting. As used in the specification, the singular forms “a”, “an” and “the” are intended to include the plural forms as well, unless the context clearly indicates otherwise. It will be further understood that the terms “comprises” and/or “comprising”, when used in the specification, specify the presence of stated features, integers, steps, operations, elements, and/or components, but do not preclude the presence or addition of one or more other features, integers, steps, operations, elements, components, and/or groups thereof.

Hereinafter, embodiments will now be described more fully with reference to accompanying drawings.

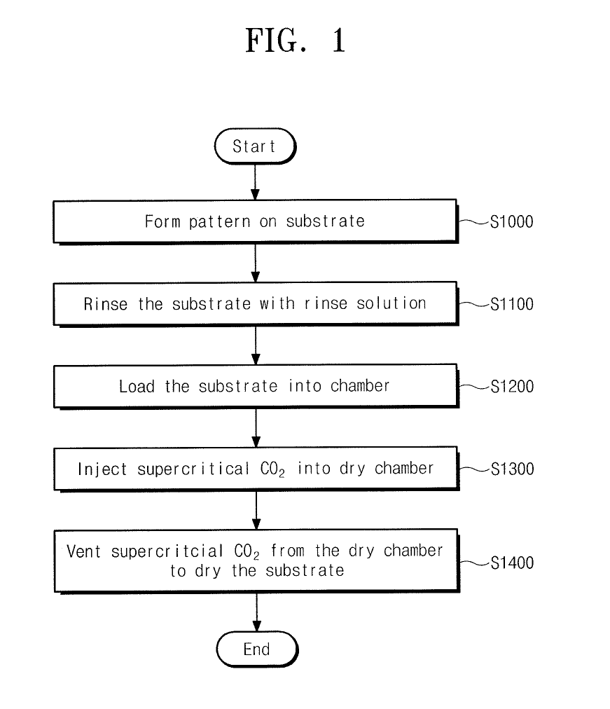

FIG. 1 illustrates a flowchart summarizing a method of rinsing and drying a semiconductor device according to an embodiment

Referring to FIG. 1, a pattern may be formed on a substrate (S1000). In one embodiment, the pattern may have an aspect ratio equal to or greater than 12. In an embodiment, the pattern may have an aspect ratio equal to or greater than 24. In an embodiment, the pattern may be provided in plurality. The plurality of patterns may be spaced apart from each other with at least 48 stages to have a vertically stacked structure.

The pattern-formed substrate may be rinsed by a rinsing process using a rinse solution (S1100). The rinsing process may be performed at a spin module. For example, the rinsing solution may be performed using the rinse solution while the substrate loaded on the spin module rotates.

According to an embodiment, deionized water (DIW) may be supplied to the pattern-formed substrate loaded on the spin module. A rinse solution including isopropyl alcohol may be supplied to the pattern-formed substrate loaded on the spin module. Should the isopropyl alcohol may remain in a liquid state, the pattern may lean, for example, due to surface tension of the isopropyl alcohol.

After the rinsing process, the pattern-formed substrate may be transferred to a dry chamber (S1200). A rinse solution such as the deionized water (DIW) and/or the isopropyl alcohol may remain on the pattern-formed substrate.

Supercritical carbon dioxide (CO₂) may be injected into the dry chamber to which the pattern-formed substrate is loaded (S1300). According to an embodiment, the supercritical carbon dioxide (CO₂) may be at a pressure of 74.8 bar or higher and a temperature of 31.1 degrees centigrade or higher. The dry chamber may be maintained at a pressure of about 80 bars or higher and a temperature of about 40 degrees centigrade or higher to maintain the supercritical carbon dioxide (CO₂). A surface tension of the supercritical carbon dioxide (CO₂) may be close to zero, and the pattern-formed substrate may be dried using the supercritical carbon dioxide (CO₂). To help avoid leaning of a pattern having a high aspect ratio, for example, due to an external force, the pattern-formed substrate may be dried using the supercritical carbon dioxide (CO₂) having a surface tension that is substantially zero, and a defect, e.g., leaning, caused by the surface tension of the rinse solution may be prevented.

The supercritical carbon dioxide (CO₂) may be injected into the dry chamber, and a concentration of the rinse solution remaining on the pattern-formed substrate may be reduced by the supercritical carbon dioxide (CO₂). According to an embodiment, the supercritical carbon dioxide (CO₂) may continue to be injected into the dry chamber until the concentration of the rinse solution remaining on the pattern-formed substrate is reduced below about 2 percent by weight based on a weight of the rinse solution remaining on the pattern-formed substrate and the supercritical carbon dioxide.

The dry chamber may be maintained at an atmospheric pressure by venting the supercritical carbon dioxide (CO₂) (S1400), and drying of the pattern-formed substrate may be completed.

As set forth above, a concentration of a rinse solution such as isopropyl alcohol may be reduced below 2 percent by weight using supercritical carbon dioxide (CO₂) having a surface tension that is close to zero, and a pattern-formed substrate may be dried to help prevent pattern leaning that may be caused by a surface tension of the rinse solution remaining on the pattern.

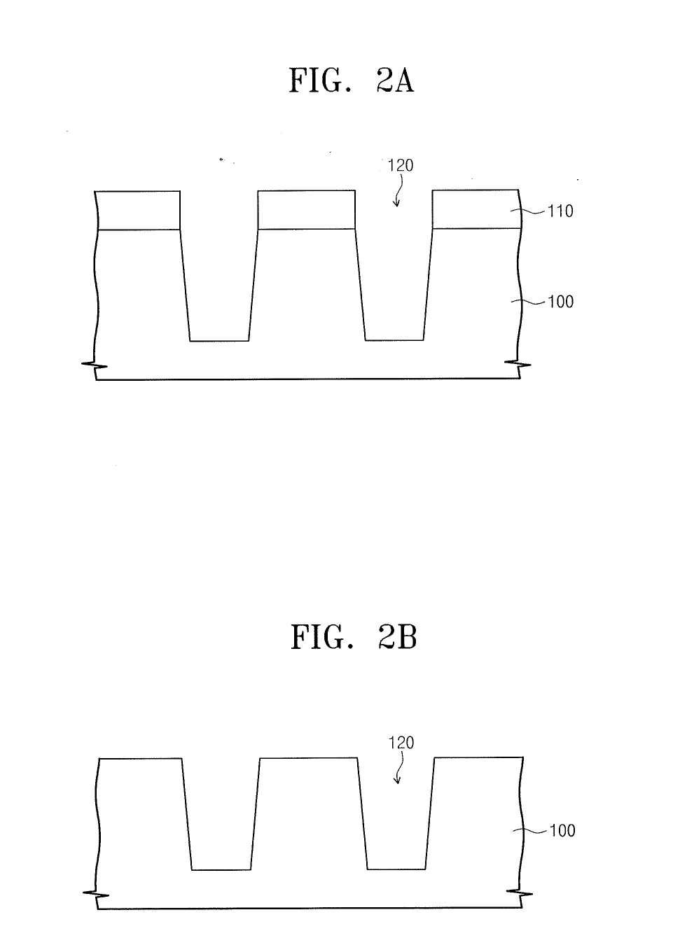

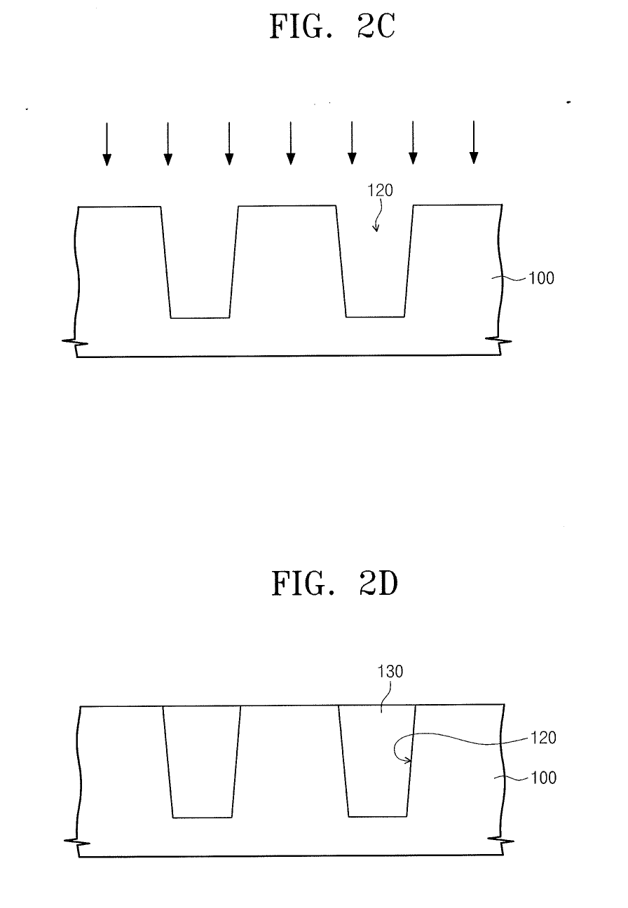

FIGS. 2A through 2D illustrate cross-sectional views of a method of manufacturing a semiconductor device according to an embodiment.

Referring to FIG. 2A, after a photoresist pattern is formed on a substrate 100, an etch process using the photoresist pattern may be performed to form a trench 120. According to an embodiment, the trench 120 may have an aspect ratio equal to or greater than 12.

Referring to FIG. 2B, the photoresist pattern 110 may be removed. The photoresist pattern 110 may be removed by means of an aching/strip process.

Referring to FIG. 2C, the substrate 100 with the trench 120 may be rinsed and dried.

For example, the rinsing may be performed at a spin module using a rinse solution including deionized water and/or isopropyl alcohol. The drying may be performed using supercritical carbon dioxide (CO₂). The details of the rinsing and drying are substantially identical to those described with reference to FIG. 1 and will not be described herein.

To help avoid leaning of the trench 120, for example, due to a surface tension of the isopropyl alcohol remaining in the trench 120, the substrate 100 may be dried using the supercritical carbon dioxide (CO₂) having a surface tension that is close to zero, and leaning of the trench 120 having an aspect ratio equal to or greater than 12 may be prevented.

Referring to FIG. 2D, the trench 120 may be filled with an insulating material to form a device isolation layer 130. For example, the insulating material may include oxide, nitride, and/or oxynitride. An active region (not shown) may be defined on the substrate 100 by the device isolation layer.

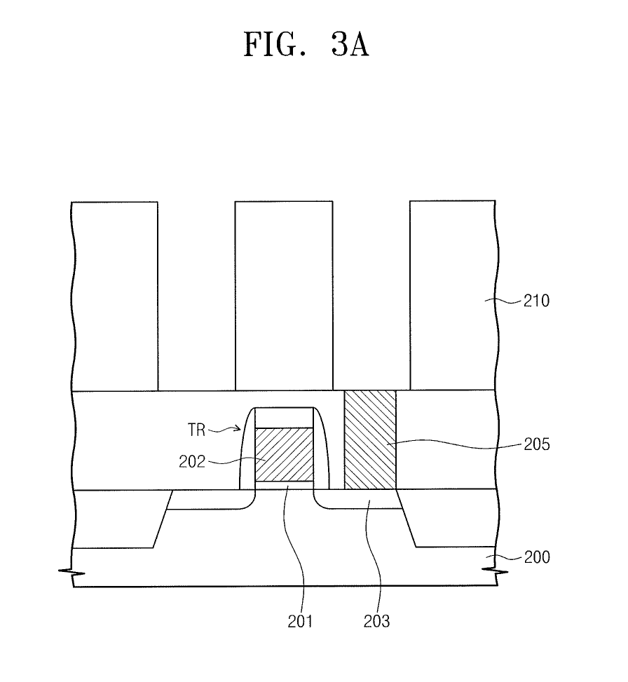

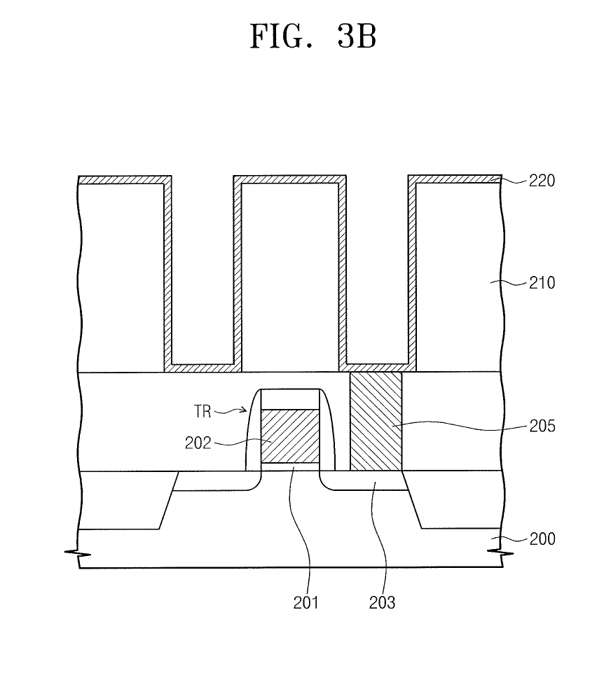

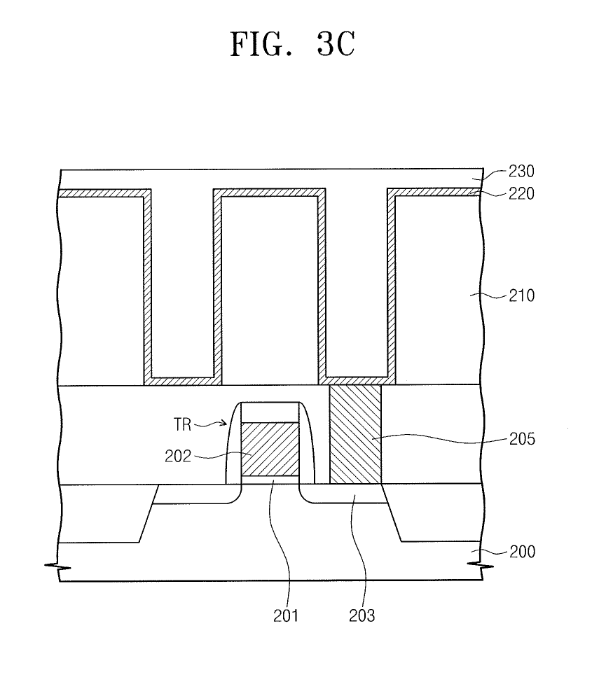

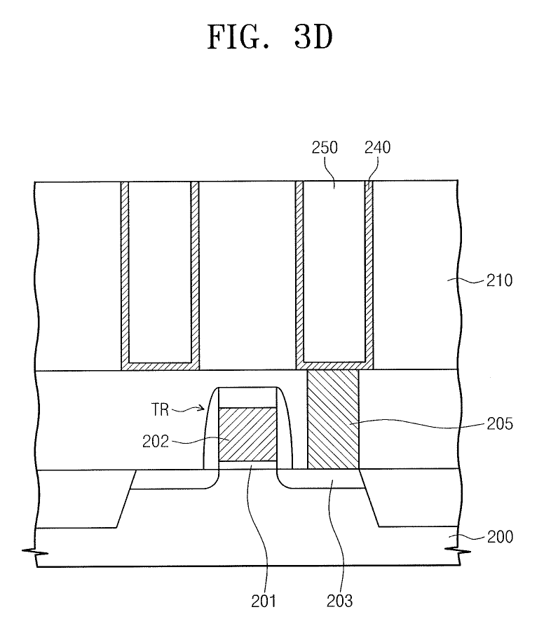

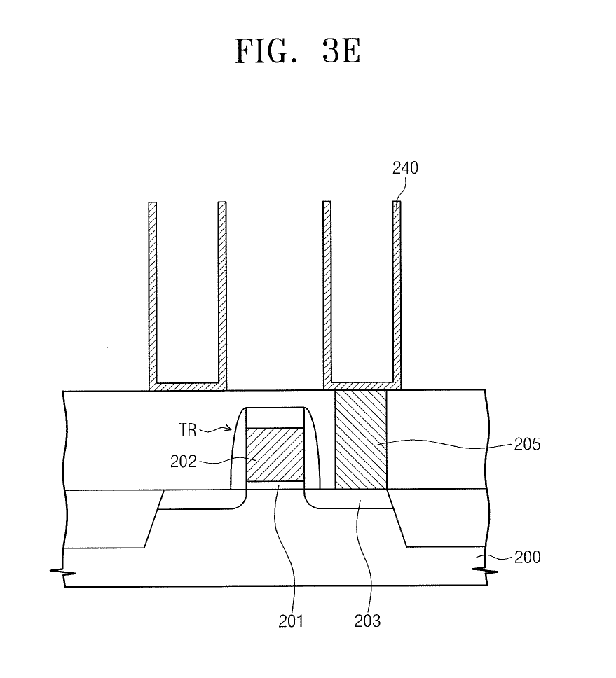

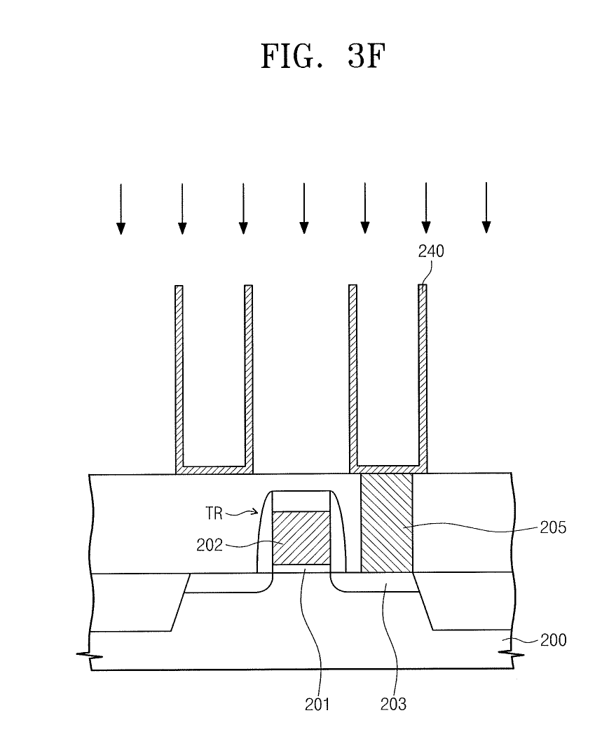

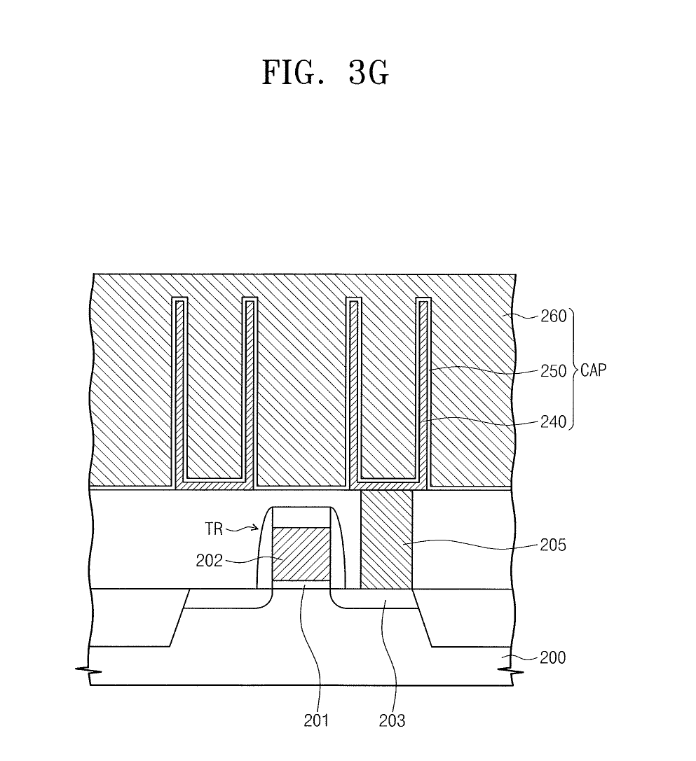

FIGS. 3A through 3G illustrate cross-sectional views of a method of manufacturing a semiconductor device according to an embodiment.

Referring to FIG. 3A, a first sacrificial pattern 210 may be formed on a substrate 200. The first sacrificial pattern 210 may include a material having an etch selectivity with respect to a working etchant and a conductive layer 220 that will be formed later. The first sacrificial pattern 210 may include oxide, nitride, oxynitride, and/or a photoresist.

According to an embodiment, a transistor TR may be formed on the substrate 200, as shown in FIG. 3A. The transistor TR may include a gate insulating layer 201, a gate electrode 202, and a source/drain region 203. One of source/drain regions 203 may be electrically connected to a first contact plug 205 to be electrically connected to a capacitor CAP (see FIG. 3G) formed in a subsequent process. Although not shown in detail, another source drain region 203 may be electrically connected to a second contact plug to be electrically connected to a bitline. A semiconductor device completed in this embodiment may be a dynamic random access memory (DRAM).

Referring to FIG. 3B, a conductive layer 220 may be conformally formed on the substrate 200 where the first sacrificial pattern 210 is formed. The conductive layer 220 may include impurity-doped polysilicon, a metal or a metal compound

Referring to FIG. 3C, a sacrificial layer 230 may be formed on the conductive layer 220. The sacrificial layer 230 may include substantially the same material as the first sacrificial pattern 210.

Referring to FIG. 3D, the sacrificial layer 230 and an upper portion of the conductive layer 220 may be etched down to a top surface of the first sacrificial pattern 210 to form a node-separated storage electrode 240 and a second sacrificial pattern 250. According to an embodiment, the storage electrode 240 may have an aspect ratio equal to or greater than 24.

Referring to FIG. 3E, the first and second sacrificial patterns 210 and 250 may be removed to expose an inner side surface and an outer side surface of the storage electrode 240.

Referring to FIG. 3F, the substrate 200 where the storage electrode 240 is formed may be rinsed and dried. For example, the rinsing may be performed at a spin module using a rinse solution including deionized water and/or isopropyl alcohol. The drying may be performed using supercritical carbon dioxide (CO₂). The details of the rinsing and drying are substantially identical to those described with reference to FIG. 1 and will not be described herein.

To help avoid leaning of the trench 120, for example, due to a surface tension of the isopropyl alcohol remaining in the trench 120, the substrate 100 may be dried using the supercritical carbon dioxide (CO₂) having a surface tension that is close to zero, and leaning of the trench 120 having an aspect ratio equal to or greater than 12 may be prevented.

To help avoid leaning of the storage electrode 240, for example, due to a surface tension of the isopropyl alcohol remaining between storage electrodes 240, the substrate 100 may be dried using the supercritical carbon dioxide (CO₂) having a surface tension that is close to zero, and leaning of the storage electrode 240 having an aspect ratio equal to or greater than 24 may be prevented.

Referring to FIG. 3G, a dielectric layer 250 and a top electrode 260 may be formed on the storage electrode 240 to form a capacitor CAP. As described above, the capacitor CAP may be electrically connected to the transistor TR through the first contact plug 205.

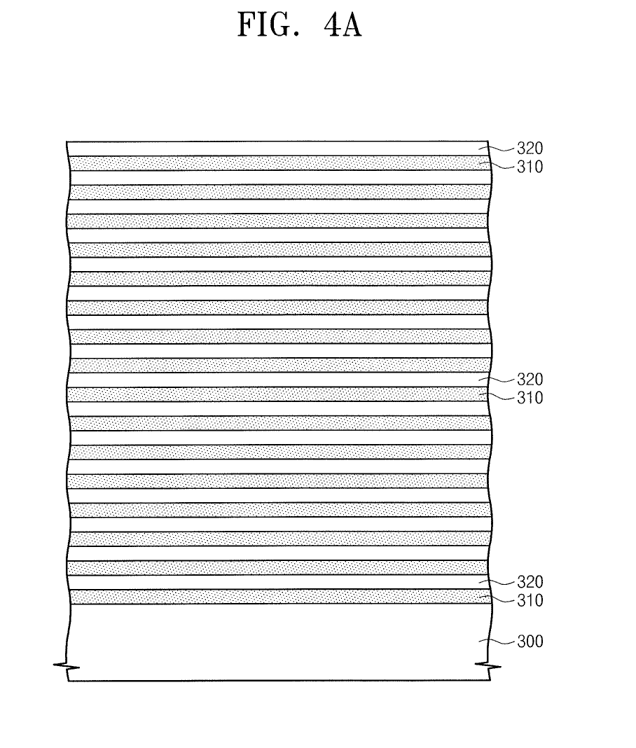

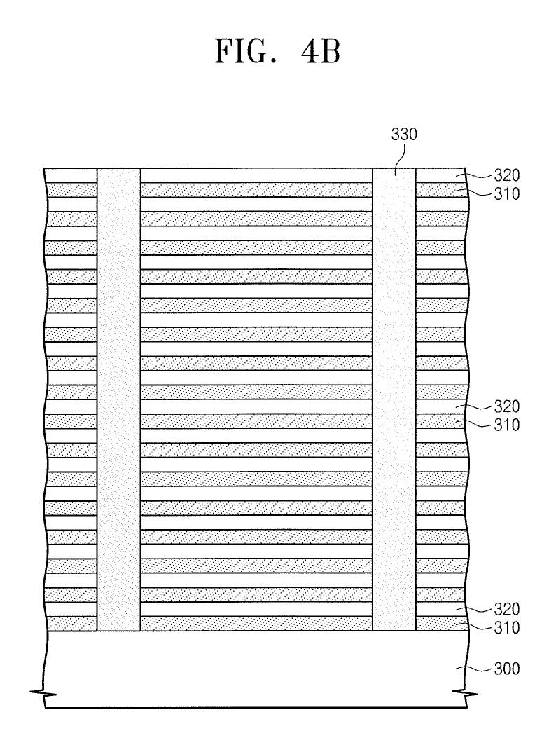

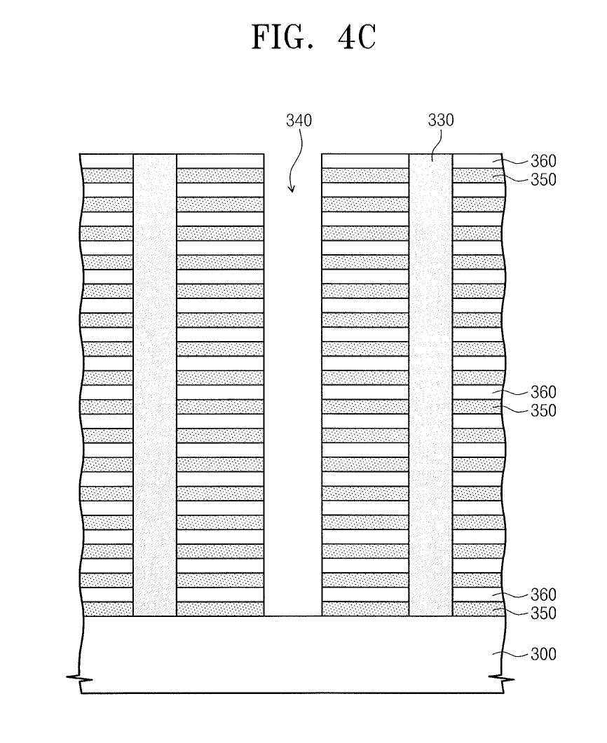

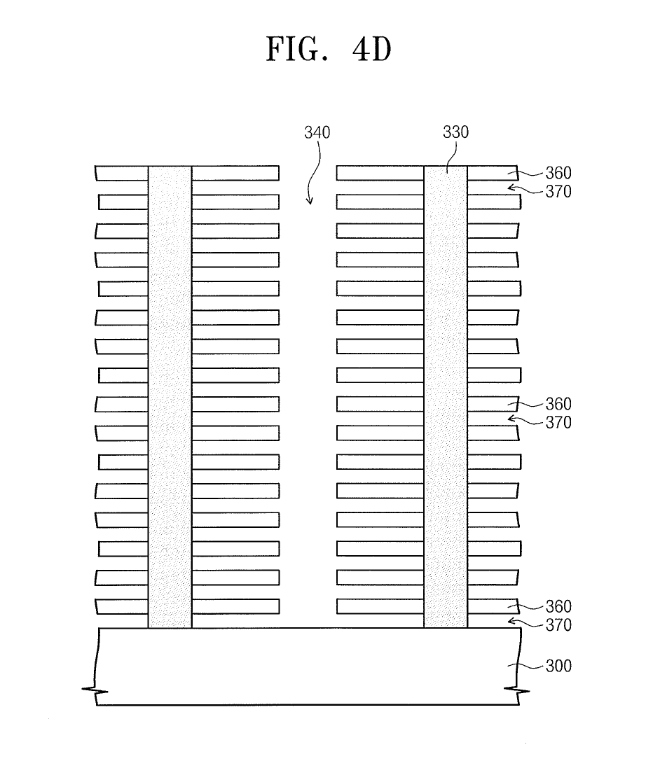

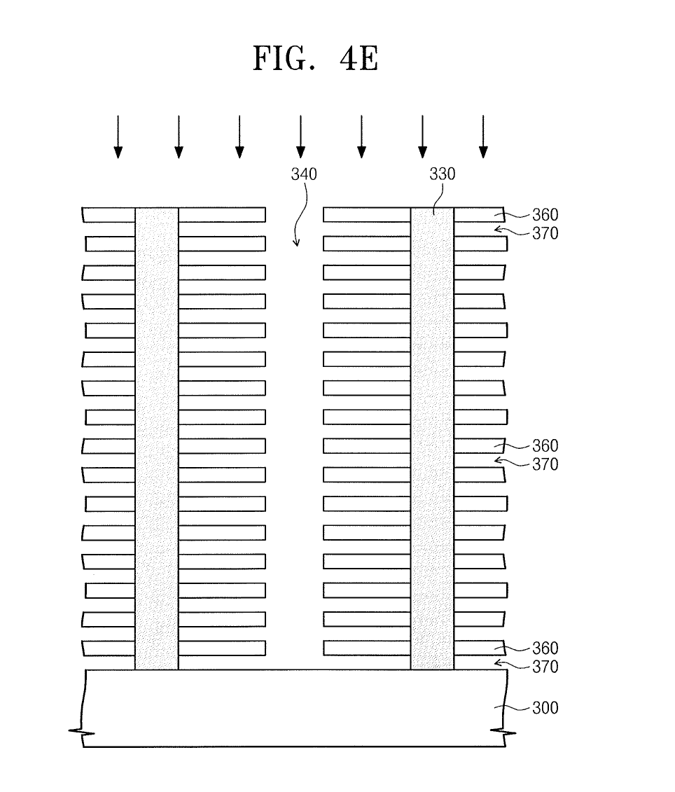

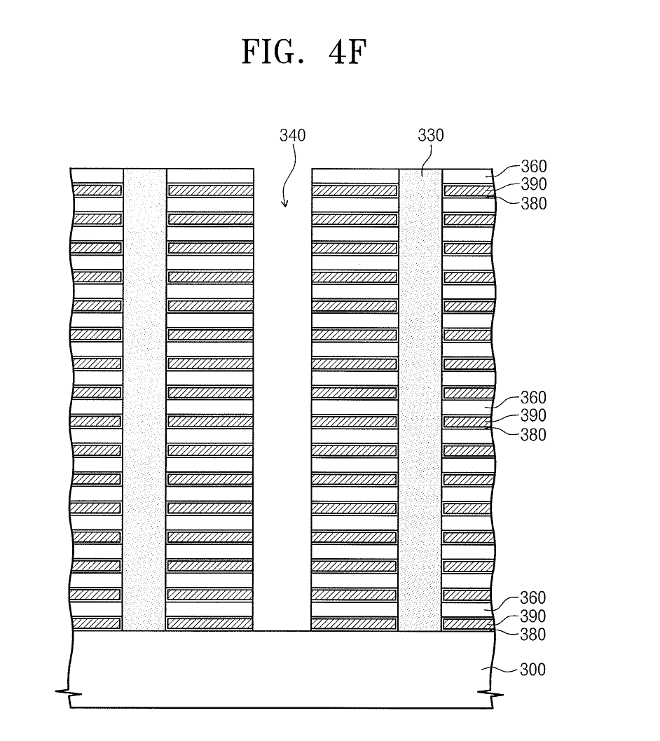

FIGS. 4A through 4F illustrate cross-sectional views of a method of manufacturing a semiconductor device according to an embodiment.

Referring to FIG. 4A, sacrificial layers 310 and interlayer dielectrics 320 may be alternately stacked on a substrate 300. Each of the sacrificial layers 310 may include a material having an etch selectivity with respect to the respective interlayer dielectrics 320 and a working etchant. Each of the interlayer dielectrics 320 may include oxide, nitride, and/or oxynitride.

Referring to FIG. 4B, a vertical active pattern 330 may be formed to penetrate the sacrificial layers 310 and the interlayer dielectrics 320. For example, a through-hole may be formed through the sacrificial layers 310 and the interlayer dielectrics 320 to expose the substrate 300. The through-hole may be filled with polysilicon to form a vertical active pattern 330.

Referring to FIG. 4C, the sacrificial layers 310 and the interlayer dielectrics 320 may be etched such that a trench 340 is formed to expose a surface of the substrate 300 and extend in one direction. The trench 340 is formed by means of the etching and, at the same time, a plurality of sacrificial patterns 350 and interlayer dielectric patterns 360 may be alternately disposed along the vertical active pattern 330.

Referring to FIG. 4D, the sacrificial patterns 350 exposed by the trench 340 may be removed to form recesses between the interlayer dielectric patterns 360. The number of the recesses 370 may be at least 48.

Referring to FIG. 4E, the substrate 300 where the interlayer dielectric patterns 360 are formed may be rinsed and dried. For example, the rinsing may be performed at a spin module using a rinse solution including deionized water and/or isopropyl alcohol. The drying may be performed using supercritical carbon dioxide (CO₂). The details of the rinsing and drying are substantially identical to those described with reference to FIG. 1 and will not be described herein.

To help avoid leaning of the trench 120, for example, due to a surface tension of the isopropyl alcohol remaining in the trench 120, the substrate 100 may be dried using the supercritical carbon dioxide (CO₂) having a surface tension that is close to zero, and leaning of the trench 120 having an aspect ratio equal to or greater than 12 may be prevented.

To help avoid leaning of the interlayer dielectrics 360, for example, due to a surface tension of the isopropyl alcohol remaining between the interlayer dielectric patterns 360, the substrate 100 may be dried using the supercritical carbon dioxide (CO₂) having a surface tension that is close to zero, and leaning of interlayer dielectric patterns 360 may be prevented.

Referring to FIG. 4F, a tunnel insulating layer 380 and a gate pattern 390 may be sequentially formed at each of the recesses 370. The formation of the tunnel insulating layer 380 and the gate pattern 390 may be carried out by means of a conventional process and will not explained in further detail.

According to the above-described embodiments, a concentration of a rinse solution such as isopropyl alcohol is reduced below 2 percent by weight using the supercritical carbon dioxide (CO₂) having a surface tension that is close to zero. Through the reduction of the concentration, a pattern-formed substrate may be dried to help prevent pattern leaning, for example, caused by a surface of the rinse solution remaining on the pattern.

The present disclosure relates to methods of rinsing and drying semiconductor devices and methods of manufacturing semiconductor devices using the method. For example, the present disclosure is directed to a method of rinsing and drying a semiconductor device with a high aspect ratio or small width between patterns and a method of manufacturing a semiconductor device using the method.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of rinsing and drying a semiconductor device, comprising:
forming a pattern on a substrate;
rinsing the substrate, where the pattern is formed, using a rinse solution;
loading the substrate into a dry chamber;
injecting supercritical carbon dioxide into the dry chamber such that rinse solution remaining on the pattern is diluted to have a concentration below 2 percent by weight based on a weight of the rinse solution remaining on the pattern and the supercritical carbon dioxide; and
venting the supercritical carbon dioxide such that the dry chamber is maintained at atmospheric pressure to dry the substrate where the pattern is formed.

2. The method as claimed in claim 1, further comprising, following injecting the supercritical carbon dioxide, maintaining the dry chamber at a temperature of 40 degrees centigrade or higher and at a pressure of 80 bars or higher.

3. The method claimed in claim 1, wherein rinsing the substrate includes:
loading the substrate on a spin module;
supplying deionized water while the substrate is rotated by the spin module; and
supplying a rinse solution including isopropyl alcohol while the substrate is rotated by the spin module.

4. The method as claimed in claim 1, wherein forming the pattern on the substrate includes etching the substrate to form a trench having an aspect ratio equal to or greater than 12.

5. The method as claimed in claim 1, wherein forming the pattern on the substrate includes:
forming a sacrificial pattern on the substrate;
conformally forming a conductive layer on the sacrificial pattern;
etching an upper portion of the conductive layer to form a node-separated storage electrode having an aspect ratio equal to or greater than 24; and
removing the sacrificial pattern.

6. The method as claimed in claim 1, wherein forming the pattern on the substrate includes:
forming sacrificial layers of at least 48 stages and interlayer dielectrics between two adjacent sacrificial layers on the substrate, respectively;
forming a vertical active pattern to penetrate the sacrificial layers and the interlayer dielectrics;
etching the sacrificial layers and the interlayer dielectrics to form a trench extending in one direction; and
removing the sacrificial layers.

7. A method of manufacturing a semiconductor device, comprising:
sequentially and alternately stacking sacrificial layers and interlayer dielectrics on a substrate;
forming a through active pattern to penetrate the sacrificial layers and the interlayer dielectrics and to be electrically connected to the substrate;
etching the sacrificial layers and the interlayer dielectrics in one direction to form a trench;
removing the sacrificial layers exposed by the trench to form recesses;
rinsing the substrate, where the interlayer dielectrics are formed, using a rinse solution;
loading the substrate into a dry chamber;
injecting supercritical carbon dioxide into the dry chamber such that the rinse solution remaining on the substrate where the interlayer dielectric are formed is diluted to have a concentration below 2 percent by weight based on a weight of the rinse solution remaining on the substrate and the supercritical carbon dioxide; and
venting the supercritical carbon dioxide to maintain the dry chamber at atmospheric pressure.

8. The method as claimed in claim 7, removing the sacrificial layers exposed by the trench to form recesses includes forming at least 48 recesses.

9. The method as claimed in claim 7, further comprising, following injecting the supercritical carbon dioxide, maintaining the dry chamber at a temperature of 40 degrees centigrade or higher and at a pressure of 80 bars or higher.

10. A method of manufacturing a semiconductor device, comprising:
forming a pattern on a substrate;
lowering surface tension of a cleaning solution used on the pattern; and
drying the substrate where the pattern is formed.

11. The method as claimed in claim 10, wherein the pattern has an aspect ratio equal to or greater than 12.

12. The method as claimed in claim 11, wherein the cleaning solution includes at least one of isopropyl alcohol and water.

13. The method as claimed in claim 12, wherein lowering surface tension of the cleaning solution includes diluting the cleaning solution with supercritical carbon dioxide.

14. The method as claimed in claim 13, wherein the supercritical carbon dioxide is at a pressure of 74.8 bar or higher and a temperature of 31.1 degrees centigrade or higher.

15. The method as claimed in claim 14, wherein the cleaning solution is diluted to have a concentration below 2 percent by weight based on a weight of the cleaning solution and the supercritical carbon dioxide.

16. The method as claimed in claim 15, wherein lowering surface tension of the cleaning solution prevents leaning of the pattern.
